(19) United States
(12) Patent Application Publication
(10) Pub. No.: US 2024/0373736 A1
(43) Pub. Date: Nov. 7, 2024

(54) Materials and Methods to Improve the Stability of Metal Halide Perovskites

(71) Applicant: The University of Toledo, Toledo, OH (US)

(72) Inventors: Yanfa Yan, Toledo, OH (US); Chongwen Li, Toledo, OH (US); Baicheng Weng, Toledo, OH (US)

(73) Assignee: The University of Toledo, Toledo, OH (US)

(21) Appl. No.: 18/768,377

(22) Filed: Jul. 10, 2024

Related U.S. Application Data
(62) Division of application No. 17/038,731, filed on Sep. 30, 2020.
(60) Provisional application No. 62/910,100, filed on Oct. 3, 2019.

(51) Int. Cl. H10K 85/30; C07F 7/22; C07F 7/24; C07F 9/50; H01G 9/00; H01G 9/20; H10K 30/30; H10K 30/82; H10K 71/12; H10K 85/60

(52) U.S. Cl. CPC H10K 85/30; C07F 7/22; C07F 7/24; C07F 9/5027; H01G 9/0036; H01G 9/2009; H01G 9/2018; H10K 30/30; H10K 30/82; H10K 71/12; H10K 85/60; H10K 85/633; H10K 85/654; H10K 85/6572; H10K 85/624

(57) ABSTRACT

Materials and methods for improving the stability of perovskites are described.

### RELATED APPLICATIONS

This is a divisional application which claims priority to U.S. application Ser. No. 17/038,731, filed under 35 U.S.C. § 111(a) on Sep. 30, 2020; which claims priority to U.S. Provisional Application No. 62/910,100 filed under 35 U.S.C. § 111(b) on Oct. 3, 2019. The entire disclosure of each of the aforementioned applications is incorporated herein by reference for all purposes.

### STATEMENT REGARDING FEDERALLY SPONSORED RESEARCH

This invention was made with no government support. The government has no rights in this invention.

### BACKGROUND

Metal halide perovskites are commonly used as absorbers in solar cells. The record power conversion efficiency (PCE) for a perovskite solar cell has reached 24.2% in 2019. Despite the excellent PCE, unsatisfactory stability against moisture, temperature, and oxygen hinders the commercialization of perovskite solar cells. In particular, halide perovskites dissolve in water. Thus, there is a need in the art for new and improved materials and methods for stabilizing and protecting metal halide perovskites from moisture.

### SUMMARY

Provided is a composition comprising a perovskite having a formula of ABX₃, wherein A is methylamine (MA), formamidine (FA), or cesium (Cs); B is lead (Pb), tin (Sn), or a combination thereof; and X is a halogen; and a hydrophobic molecule bonded to the perovskite, wherein the hydrophobic molecule forms a coordination bond with the lead or tin in the perovskite. Also provided is an article comprising the composition, wherein the article comprises a light-emitting diode, a solar cell, or a photodetector.

In certain embodiments, the hydrophobic molecule comprises a diphosphine. In certain embodiments, the hydrophobic molecule comprises 1,3-bis(diphenylphosphino)propane (dppp). In certain embodiments, the hydrophobic molecule is selected from the group consisting of: 1,3-bis(diphenylphosphino)propane (dppp), 1,1-bis(diphenylphosphino)methane (dppm), bis(dicyclohexylphosphinoe)methane (dcpm), 1,2-bis(dimethylphosphino)ethane (dmpe), bis(diisopropylphosphino)methane (dippm), 1,2-bis(diisopropylphosphino(ethane) (dippe), 1,3-bis(diisopropylphosphino)propane (dippp), 1,2-bis(diphenylphosphino)ethane (dppe), bis(dimethylphosphino)methane (dmpm), 1,3-bis(dicyclohexylphosphino)propane (dcpp), ethane-1,2-diylbis[(2-methoxyphenyl)phenylphosphane] (DIPAMP), bis(dicyclohexylphosphino)ethane (dcpe), 1,3-bis(dimethylphosphino)propane (dmpp), 1,4-bis(diphenylphosphino)butane (dppb), diphosphine-1,1,2,2-tetraphenyl propane, 1,1-bis(diphenylphosphino)ethylene, 0-isopropylidene-2,3-dihydroxy-1,4-bis(diphenylphosphino)butane (DIOP), butane-2,3-diylbis(diphenylphosphane) (BINAP), butane-2,3-diylbis(diphenylphosphane) (chiraphos), 4,5-bis(diphenylphosphino)-9,9-dimethylxanthene (xantphos), 4,4,4′,4′,6,6′-hexamethyl-2,2′-spirobichromane-8,8′-diylbis(diphenylphosphane) (SPANphos), 4,4′-bi-1,3-benzodioxole-5,5′-diylbis(diphenylphosphane) (SEGPHOS), 1,1′-bis(diphenylphosphino)ferrocene (dppf), 1,2-phenylenebis(2,5-dimethylphospholane) (Me-DuPhos), and combinations thereof.

In certain embodiments, the hydrophobic molecule comprises a dinitrogen compound. In certain embodiments, the hydrophobic molecule is selected from the group consisting of: 4,4′-bipyridine, 4,4′-ethylenedipyridine, 4,4′-trimethylenedipyridine, (1R,2R)-(−)-1,2-diaminocyclohexane, 2,2′-bipyridine, 2,2′-dipyridylamine, 1,10-phenanthroline, benzil bis(thiosemicarbazone), and combinations thereof.

In certain embodiments, the hydrophobic molecule comprises a metal-dioxygen complex.

In certain embodiments, the halogen is iodine, bromine, or chlorine.

In certain embodiments, the perovskite comprises FAPbI₃.

In certain embodiments, the perovskite is in an optoelectronic device. In particular embodiments, the optoelectronic device is a light-emitting diode, a solar cell, or a photodetector.

Further provided is a solar cell comprising a front contact comprising a first electrically conductive material; a photovoltaic heterojunction on the front contact, wherein the photovoltaic heterojunction is formed between a first semiconductor layer and a second semiconductor layer, the second semiconductor layer comprising an absorber, wherein the absorber comprises a metal halide perovskite having a formula of ABX₃ wherein: A is methylamine (MA), formamidine (FA), or cesium (Cs), B is lead (Pb), tin (Sn), or a combination thereof, and X is a halogen; and a hydrophobic molecule bonded to the metal halide perovskite, wherein the hydrophobic molecule coordinates with the lead or tin in the metal halide perovskite; and a back contact comprising a second electrically conductive material on the absorber layer.

In certain embodiments, the hydrophobic molecule comprises a diphosphine. In certain embodiments, the hydrophobic molecule comprises 1,3-bis(diphenylphosphino)propane (dppp). In certain embodiments, the hydrophobic molecule is selected from the group consisting of: 1,3-bis(diphenylphosphino)propane (dppp), 1,1-bis(diphenylphosphino)methane (dppm), bis(dicyclohexylphosphinoe)methane (dcpm), 1,2-bis(dimethylphosphino)ethane (dmpe), bis(diisopropylphosphino)methane (dippm), 1,2-bis(diisopropylphosphino(ethane) (dippe), 1,3-bis(diisopropylphosphino)propane (dippp), 1,2-bis(diphenylphosphino)ethane (dppe), bis(dimethylphosphino)methane (dmpm), 1,3-bis(dicyclohexylphosphino)propane (dcpp), ethane-1,2-diylbis[(2-methoxyphenyl)phenylphosphane] (DIPAMP), bis(dicyclohexylphosphino)ethane (dcpe), 1,3-bis(dimethylphosphino)propane (dmpp), 1,4-bis(diphenylphosphino)butane (dppb), diphosphine-1,1,2,2-tetraphenyl propane, 1,1-bis(diphenylphosphino)ethylene, 0-isopropylidene-2,3-dihydroxy-1,4-bis(diphenylphosphino)butane (DIOP), butane-2,3-diylbis(diphenylphosphane) (BINAP), butane-2,3-diylbis(diphenylphosphane) (chiraphos), 4,5-bis(diphenylphosphino)-9,9-dimethylxanthene (xantphos), 4,4,4′,4′,6,6′-hexamethyl-2,2′-spirobichromane-8,8′-diylbis(diphenylphosphane) (SPANphos), 4,4′-bi-1,3-benzodioxole-5,5′-diylbis(diphenylphosphane) (SEGPHOS), 1,1′-bis(diphenylphosphino)ferrocene (dppf), 1,2-phenylenebis(2,5-dimethylphospholane) (Me-DuPhos), and combinations thereof.

In certain embodiments, the hydrophobic molecule comprises a dinitrogen compound. In certain embodiments, hydrophobic molecule is selected from the group consisting of: 4,4′-bipyridine, 4,4′-ethylenedipyridine, 4,4′-trimethylenedipyridine, (1R,2R)-(−)-1,2-diaminocyclohexane, 2,2′-bipyridine, 2,2′-dipyridylamine, 1,10-phenanthroline, benzil bis(thiosemicarbazone), and combinations thereof.

In certain embodiments, the hydrophobic molecule comprises a metal-dioxygen complex.

In certain embodiments, the solar cell further comprises a hole transport layer disposed between the absorber layer and the back contact. In particular embodiments, the hole transport layer comprises 2,2′,7,7′-tetrakis[N,N-di(4-methoxyphenyl)amino]-9,9′-spirobifluorene (spiro-OMETAD).

In certain embodiments, the perovskite comprises FAPbI₃.

Further provided is a method for improving the stability of a perovskite, the method comprising incorporating a diphosphine, a dinitrogen compound, or a metal-dioxygen complex into the perovskite and improving the stability of the perovskite.

In certain embodiments, the diphosphine molecule comprises 1,3-bis(diphenylphosphino)propane (dppp). In certain embodiments, the diphosphine is selected from the group consisting of: 1,3-bis(diphenylphosphino)propane (dppp), 1,1-bis(diphenylphosphino)methane (dppm), bis(dicyclohexylphosphinoe)methane (dcpm), 1,2-bis(dimethylphosphino)ethane (dmpe), bis(diisopropylphosphino)methane (dippm), 1,2-bis(diisopropylphosphino(ethane) (dippe), 1,3-bis(diisopropylphosphino)propane (dippp), 1,2-bis(diphenylphosphino)ethane (dppe), bis(dimethylphosphino)methane (dmpm), 1,3-bis(dicyclohexylphosphino)propane (dcpp), ethane-1,2-diylbis[(2-methoxyphenyl)phenylphosphane](DIPAMP), bis(dicyclohexylphosphino)ethane (dcpe), 1,3-bis(dimethylphosphino)propane (dmpp), 1,4-bis(diphenylphosphino)butane (dppb), diphosphine-1,1,2,2-tetraphenyl propane, 1,1-bis(diphenylphosphino)ethylene, O-isopropylidene-2,3-dihydroxy-1,4-bis(diphenylphosphino)butane (DIOP), butane-2,3-diylbis(diphenylphosphane) (BINAP), butane-2,3-diylbis(diphenylphosphane) (chiraphos), 4,5-bis(diphenylphosphino)-9,9-dimethylxanthene (xantphos), 4,4,4′,4′,6,6′-hexamethyl-2,2′-spirobichromane-8,8′-diylbis(diphenylphosphane) (SPANphos), 4,4′-bi-1,3-benzodioxole-5,5′-diylbis(diphenylphosphane) (SEGPHOS), 1,1′-bis(diphenylphosphino)ferrocene (dppf), 1,2-phenylenebis(2,5-dimethylphospholane) (Me-DuPhos), and combinations thereof.

In certain embodiments, the dinitrogen compound comprises 4,4′-bipyridine, 4,4′-ethylenedipyridine, 4,4′-trimethylenedipyridine, (1R,2R)-(−)-1,2-diaminocyclohexane, 2,2′-bipyridine, 2,2′-dipyridylamine, 1,10-phenanthroline, benzil bis(thiosemicarbazone), or combinations thereof.

In certain embodiments, the perovskite is in an optoelectronic device. In particular embodiments, the optoelectronic device comprises a solar cell, a photodetector, or a light-emitting diode (LED).

In certain embodiments, the perovskite comprises a metal halide perovskite having a formula of ABX₃ wherein A is methylamine (MA), formamidine (FA), or cesium (Cs), B is lead (Pb), tin (Sn), or a combination thereof, and X is a halogen. In certain embodiments, the perovskite comprises FAPbI₃.

Further provided is a method for making an optoelectronic device, the method comprising depositing a perovskite layer on a substrate, and incorporating a hydrophobic diphosphine, dinitrogen compound, or metal-dioxygen complex into the perovskite layer.

In certain embodiments, the perovskite comprises a metal halide perovskite having a formula of ABX₃ wherein A is methylamine (MA), formamidine (FA), or cesium (Cs), B is lead (Pb), tin (Sn), or a combination thereof, and X is a halogen. In certain embodiments, the perovskite comprises FAPbI₃.

In certain embodiments, the hydrophobic diphosphine molecule comprises 1,3-bis(diphenylphosphino)propane (dppp). In certain embodiments, the hydrophobic diphosphine molecule is selected from the group consisting of: 1,3-bis(diphenylphosphino)propane (dppp), 1,1-bis(diphenylphosphino)methane (dppm), bis(dicyclohexylphosphinoe)methane (dcpm), 1,2-bis(dimethylphosphino)ethane (dmpe), bis(diisopropylphosphino)methane (dippm), 1,2-bis(diisopropylphosphino(ethane) (dippe), 1,3-bis(diisopropylphosphino)propane (dippp), 1,2-bis(diphenylphosphino)ethane (dppe), bis(dimethylphosphino)methane (dmpm), 1,3-bis(dicyclohexylphosphino)propane (dcpp), ethane-1,2-diylbis[(2-methoxyphenyl)phenylphosphane](DIPAMP), bis(dicyclohexylphosphino)ethane (dcpe), 1,3-bis(dimethylphosphino)propane (dmpp), 1,4-bis(diphenylphosphino)butane (dppb), diphosphine-1,1,2,2-tetraphenyl propane, 1,1-bis(diphenylphosphino)ethylene, O-isopropylidene-2,3-dihydroxy-1,4-bis(diphenylphosphino)butane (DIOP), butane-2,3-diylbis(diphenylphosphane) (BINAP), butane-2,3-diylbis(diphenylphosphane) (chiraphos), 4,5-bis(diphenylphosphino)-9,9-dimethylxanthene (xantphos), 4,4,4′,4′,6,6′-hexamethyl-2,2′-spirobichromane-8,8′-diylbis(diphenylphosphane) (SPANphos), 4,4′-bi-1,3-benzodioxole-5,5′-diylbis(diphenylphosphane) (SEGPHOS), 1,1′-bis(diphenylphosphino)ferrocene (dppf), 1,2-phenylenebis(2,5-dimethylphospholane) (Me-DuPhos), and combinations thereof.

In certain embodiments, the dinitrogen compound comprises 4,4′-bipyridine, 4,4′-ethylenedipyridine, 4,4′-trimethylenedipyridine, (1R,2R)-(−)-1,2-diaminocyclohexane, 2,2′-bipyridine, 2,2′-dipyridylamine, 1,10-phenanthroline, benzil bis(thiosemicarbazone), or combinations thereof.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIG. 1: Molecular structure of 1,3-bis(diphenylphosphino)propane (dppp). The phosphorus atoms are shown in purple.

FIG. 2: Illustration showing the coordination of dppp to a perovskite. The phosphorus atoms of dppp are shown in purple.

FIGS. 3A-3B: SEM images of a perovskite without (FIG. 3A) and with (FIG. 3B) dppp coordination.

FIG. 4: Performance of perovskite devices with and without dppp.

FIGS. 5A-5C: Photographs of perovskite devices with (FIG. 5A) and without (FIG. 5B) dppp, and their efficiency tendency (FIG. 5C). In FIG. 5C, the device with dppp is shown with black dots, and the control device without dppp is shown with red dots.

FIGS. 6A-6B: Photographs of devices with (FIG. 6A) and without (FIG. 6B) dppp in a beaker of water.

FIG. 7: Schematic of a non-limiting example embodiment of a perovskite solar cell in accordance with the present disclosure.

### DETAILED DESCRIPTION

Throughout this disclosure, various publications, patents, and published patent specifications are referenced by an identifying citation. The disclosures of these publications, patents, and published patent specifications are hereby incorporated by reference into the present disclosure in their entirety to more fully describe the state of the art to which this invention pertains.

Metal halide perovskites generally have a formula of ABX₃, where A is methylamine (MA), formamidine (FA), or cesium (Cs), B is lead (Pb), tin (Sn), or a combination thereof, and X is a halogen such as iodine (I), bromine (Br), or chlorine (Cl). To address the moisture-induced instability issue of metal halide perovskites, hydrophobic materials may be induced on perovskite surfaces and grain boundaries to prevent water molecules from ingression. However, currently used molecules have significant disadvantages. First, some molecules have both hydrophobic and hydrophilic groups. Second, most molecules do not chemically bind halide perovskites. Therefore, so far, the molecules used to protect metal halide perovskites from water attack are not very efficient.

In accordance with the present disclosure, a hydrophobic molecule that chemically binds to metal halide perovskites, by forming coordination bonds with the lead and/or tin in the metal halide perovskites, may be used to effectively protect metal halide perovskites from water attack.

In general, the hydrophobic molecule used to protect the metal halide perovskite is hydrophobic, and has an ability to coordinate with lead, tin, or a combination of lead and tin. It is further advantageous if the hydrophobic molecule has a reasonably good carrier mobility so as to not hinder the flow of charge carriers in a device. However, this is not strictly necessary. Suitable hydrophobic molecules include, but are not limited to, diphosphine-containing organic compounds, particularly diphosphine-containing organic compounds having hydrophobic moieties, such as those that include one or more phenyl rings.

Diphosphines, or bisphosphanes, are organophosphorus compounds used in catalytic chemistry as bidentate phosphine ligands. In general, diphosphines include two phosphino groups linked by a backbone which gives the compound overall shape. Different diphosphines may be composed of different linkers and R-groups, and the alteration of the linkers and R-groups alters the electronic and steric properties which results in different coordination geometries and catalytic behavior. Diphosphines chelate with most metals by the two phosphine substituents forming chelate rings. For example, one diphosphine ligand is 1,2-bis(diphenylphosphino)ethane (dppe), which can form a five-membered chelate ring with metals.

In general, a diphosphine may have the following structural formula (I):

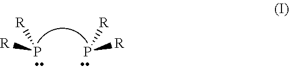

where each R may be any substituent, though in some embodiments one or more R groups comprises a hydrophobic moiety.

Non-limiting examples of suitable diphosphines include 1,3-bis(diphenylphosphino)propane (dppp), 1,1-bis(diphenylphosphino)methane (dppm), bis(dicyclohexylphosphinoe)methane (dcpm), 1,2-bis(dimethylphosphino)ethane (dmpe), bis(diisopropylphosphino)methane (dippm), 1,2-bis(diisopropylphosphino(ethane) (dippe), 1,3-bis(diisopropylphosphino)propane (dippp), 1,2-bis(diphenylphosphino)ethane (dppe), bis(dimethylphosphino)methane (dmpm), 1,3-bis(dicyclohexylphosphino)propane (dcpp), ethane-1,2-diylbis[(2-methoxyphenyl)phenylphosphane] (DIPAMP), bis(dicyclohexylphosphino)ethane (dcpe), 1,3-bis(dimethylphosphino)propane (dmpp), 1,4-bis(diphenylphosphino)butane (dppb), diphosphine-1,1,2,2-tetraphenyl propane, 1,1-bis(diphenylphosphino)ethylene, 0-isopropylidene-2,3-dihydroxy-1,4-bis(diphenylphosphino)butane (DIOP), butane-2,3-diylbis(diphenylphosphane) (BINAP), butane-2,3-diylbis(diphenylphosphane) (chiraphos), 4,5-bis(diphenylphosphino)-9,9-dimethylxanthene (xantphos), 4,4,4′,4′,6,6′-hexamethyl-2,2′-spirobichromane-8,8′-diylbis(diphenylphosphane) (SPANphos), 4,4′-bi-1,3-benzodioxole-5,5′-diylbis(diphenylphosphane) (SEGPHOS), 1,1′-bis(diphenylphosphino)ferrocene (dppf), 1,2-phenylenebis(2,5-dimethylphospholane) (Me-DuPhos), and combinations thereof.

As one example from the above list, dppp has a formula of (C₆H₅)₂P(CH₂)₃P(C₆H₅)₂ and the following chemical structure:

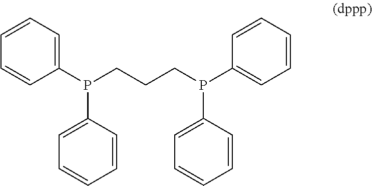 [SMILES: c1ccc(P(CCCP(c2ccccc2)c2ccccc2)c2ccccc2)cc1]

As another example dppm has a formula of (C₆H₅)₂PCH₂P(C₆H₅)₂ and the following chemical structure:

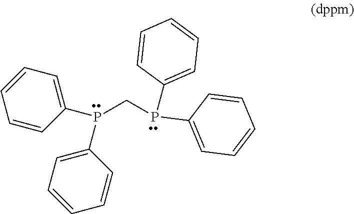 [SMILES: c1ccc(P(CP(c2ccccc2)c2ccccc2)c2ccccc2)cc1]

As another example, dppe has a formula of (C₆H₅)₂P(CH₂)₂P(C₆H₅)₂ and the following chemical structure:

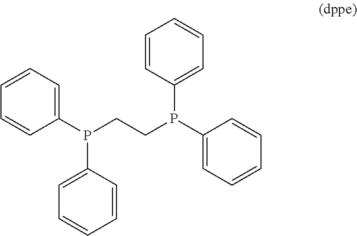 [SMILES: c1ccc(P(CCP(c2ccccc2)c2ccccc2)c2ccccc2)cc1]

As another example, dcpm has a formula of (C₆H₁₁)₂PCH₂P(C₆H₁₁)₂ and the following chemical structure:

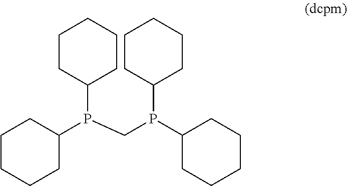 [SMILES: C1CCC(P(CP(C2CCCCC2)C2CCCCC2)C2CCCCC2)CC1]

As another example, dcpe has a formula of (C₆H₁₁)₂P(CH₂)₂P(C₆H₁₁)₂ and the following chemical structure:

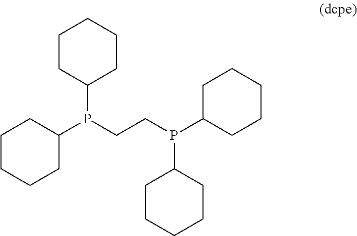 [SMILES: C1CCC(P(CCP(C2CCCCC2)C2CCCCC2)C2CCCCC2)CC1]

As another example, dcpp has a formula of (C₆H₁₁)₂P(CH₂)₃P(C₆H₁₁)₂ and the following chemical structure:

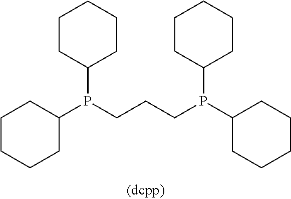 [SMILES: C1CCC(P(CCCP(C2CCCCC2)C2CCCCC2)C2CCCCC2)CC1]

As another example dmpm has a formula of (CH₃)₂PCH₂P(CH₃)₂ and the following chemical structure:

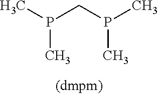

As another example, dmpe has a formula of (CH₃)₂P(CH₂)₂P(CH₃)₂ and the following chemical structure:

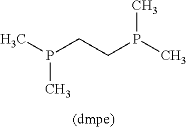

As another example, dmpp has a formula of (CH₃)₂P(CH₂)₃P(CH₃)₂ and the following chemical structure:

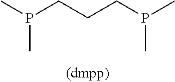

As another example, dippm has a formula of ((CH₃)₂CH)₂PCH₂P((CH₃)₂CH)₂ and the following chemical structure:

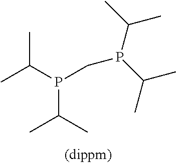

As another example, dippe has a formula of ((CH₃)₂CH)₂P(CH₂)₂P((CH₃)₂CH)₂ and the following chemical structure:

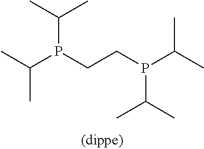 [SMILES: CC(C)P(CCP(C(C)C)C(C)C)C(C)C]

As another example, dippp has a formula of ((CH₃)₂CH)₂P(CH₂)₃P((CH₃)₂CH)₂ and the following chemical structure:

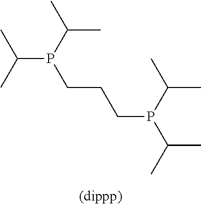 [SMILES: CC(C)P(CCCP(C(C)C)C(C)C)C(C)C]

Other suitable hydrophobic molecules include dinitrogen compounds, such as, but not limited to: 4,4′-bipyridine, 4,4′-ethylenedipyridine, 4,4′-trimethylenedipyridine, (1R,2R)-(−)-1,2-diaminocyclohexane, 2,2′-bipyridine, 2,2′-dipyridylamine, 1,10-phenanthroline, benzil bis(thiosemicarbazone), or combinations thereof.

4,4′-Bipyridine has a formula of C₁₀H₈N₂ and the following chemical structure:

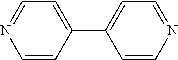 [SMILES: c1cc(-c2ccncc2)ccn1]

4,4′-Ethylenedipyridine has a formula of C₁₂H₁₂N₂ and the following chemical structure:

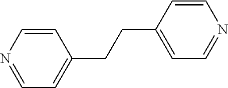 [SMILES: c1cc(CCc2ccncc2)ccn1]

4,4′-Trimethylenedipyridine has a formula of C₁₃H₁₄N₂ and the following chemical structure:

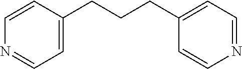 [SMILES: c1cc(CCCc2ccncc2)ccn1]

(1R,2R)-(−)-1,2-Diaminocyclohexane has a formula of C₆H₁₀(NH₂)₂ and the following chemical structure:

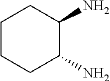

2,2′-Bipyridine has a formula of C₁₀H₈N₂ and the following chemical structure:

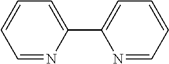 [SMILES: c1ccc(-c2ccccn2)nc1]

2,2′-Dipyridylamine has a formula of C₁₀H₉N₃ and the following chemical structure:

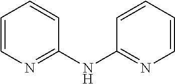 [SMILES: c1ccc(Nc2ccccn2)nc1]

1,10-Phenanthroline has a formula of C₁₂H₈N₂ and the following chemical structure:

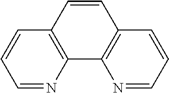 [SMILES: c1cnc2c(c1)ccc1cccnc12]

Benzil bis(thiosemicarbazone) has a formula of C₁₆H₁₆N₆S₂ and the following chemical structure:

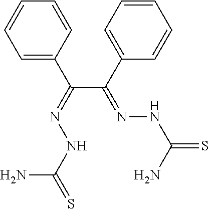 [SMILES: NC(=S)N/N=C(\C(=N\NC(N)=S)c1ccccc1)c1ccccc1]

Other suitable hydrophobic molecules include, but are not limited to, dioxygens, which are metal-dioxygen complexes.

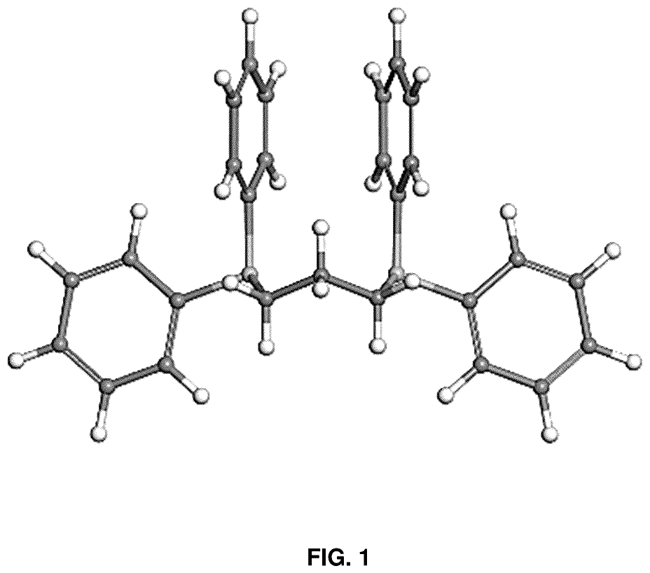

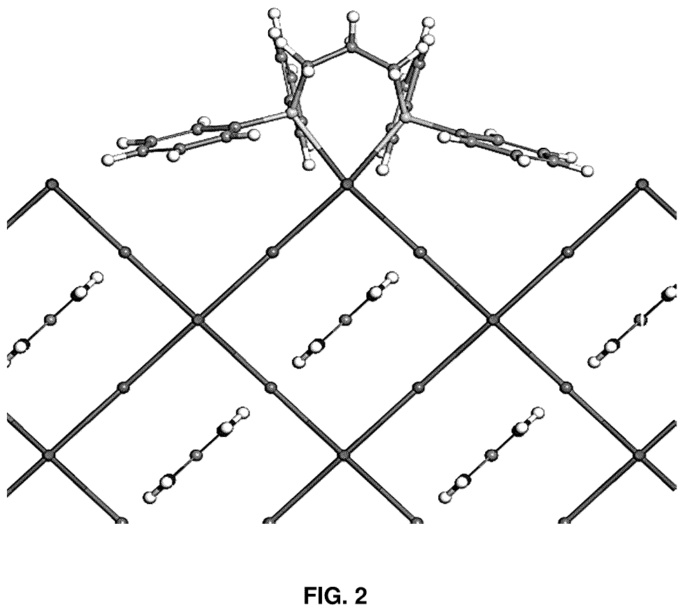

To further describe one non-limiting example, dppp is a diphosphine ligand in coordination chemistry, having only hydrophobic terminals. FIG. 1 shows the structure of dppp. Dppp is a white powder with the formula of Ph₂P(CH₂)₃PPh₂, where Ph is C₆H₅, that can be dissolved in organic solvents. The diphosphine can serve as a strong coordination ligand to metals such as Pb and Sn by the orbital hybridization of a 3 p orbital from phosphorus and the 6 s, 6 p orbitals from the metal. (FIG. 2.) Thus, dppp forms strong and stable coordination bonds to Pb or Sn atoms. The bonded 4 benzene rings from each molecule are hydrophobic, which protect the material from moisture attack. The selective coordination helps passivate dangling bonds and defects, as shown in FIG. 2, which prevent water from ingression and improve device stability. In some embodiments, the coordinated material may even be submerged in water for a prolonged period of time without degrading.

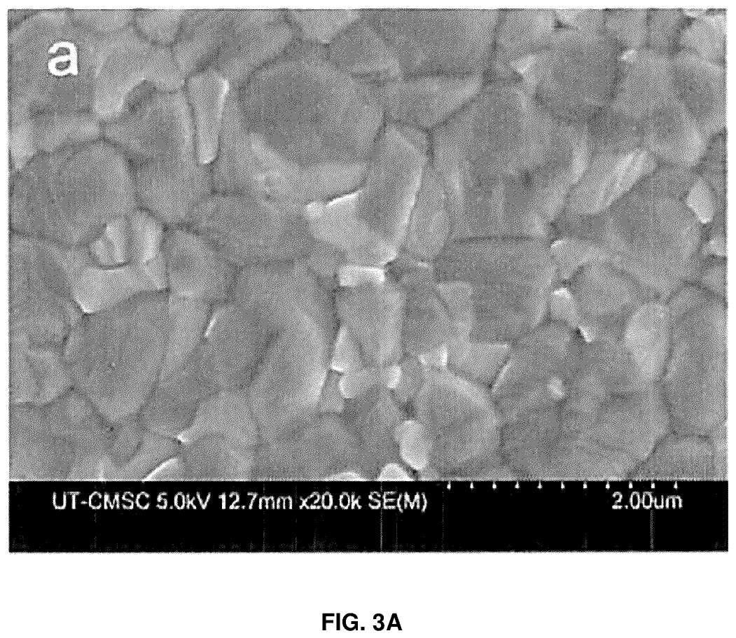

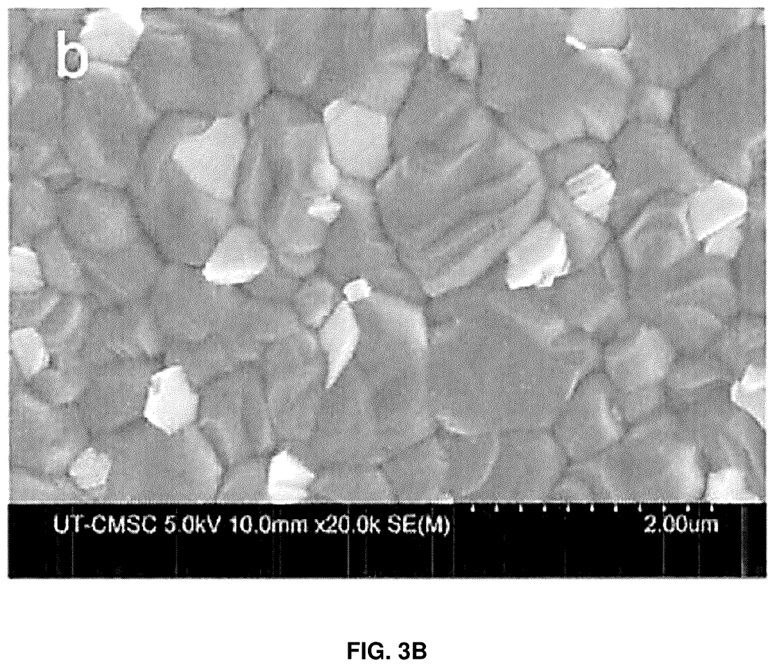

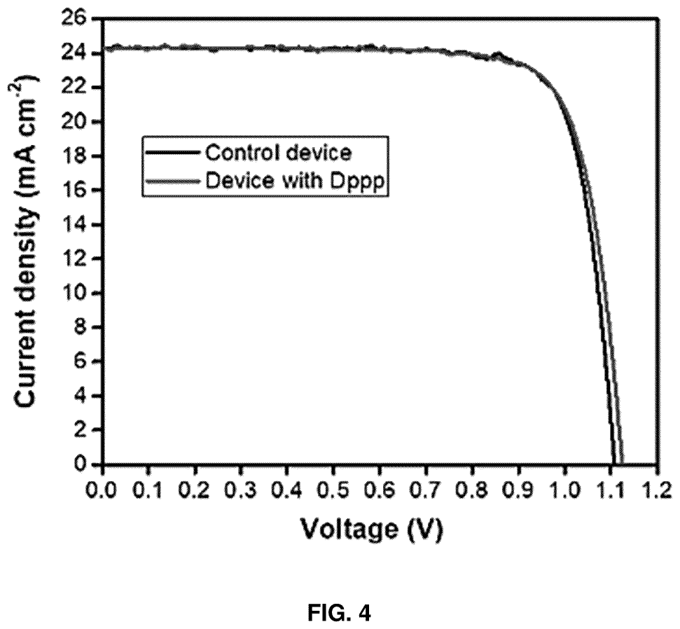

Moisture attacks the defect sites and grain boundaries in perovskite materials. The hydrophobic molecule binds at the defect sites and grain boundaries, making them inert to moisture. For example, the coordination reaction between dppp and perovskite tends to happen at surfaces and interfaces, thereby incorporating the hydrophobic dppp at sites of the perovskite material prone to moisture attack, making the coordinated perovskite robust to moisture. For example, PbI₂ on grain boundaries is a typical by-product existing on perovskite films fabricated by a two-step method. (FIG. 3A.) Excess PbI₂ is considered an effective passivation agent that helps reduce carrier recombination. Dppp reacts with the PbI₂ on grain boundaries and generates the hydrophobic complex PbI₂ (dppp), as seen in FIG. 3B. Advantageously, the binding of the hydrophobic molecule at the defect sites and grain boundaries further improves the quality of the film because it reduces the number of carrier recombinations taking place at the defect sites and grain boundaries. This is evidenced by the improved open circuit voltage from the solar cells that include the hydrophobic molecule dppp in the examples herein. (FIG. 4.) Furthermore, the hydrophobic molecule helps physically hold the materials in place so that they do not move. The hydrophobic molecule may act as a binder, preventing ions from moving through the material.

The hydrophobic molecule may be used to stabilize any chemical species that contains lead, tin, or both lead and tin. The hydrophobic molecule may coordinate with, and protect from moisture, perovskites containing both lead and tin. Moreover, the present disclosure is not limited in use to perovskites. As one non-limiting alternative example, the hydrophobic molecule may be used to protect PbS from moisture.

As demonstrated in the examples herein, a hydrophobic molecule such as dppp may be incorporated into a metal halide perovskite to provide the resulting film with improved stability against water. The hydrophobic molecule may be incorporated into perovskite films in a variety of ways. Though two example methods are described herein, the incorporation of the hydrophobic molecule into perovskite films is by no means limiting to these two example methods.

In a first non-limiting example method, the hydrophobic molecule may be incorporated into a perovskite through a spin coating process. For example, a perovskite precursor and the hydrophobic molecule can be mixed in a suitable solvent to create a mixed solution that is then spin coated onto a substrate and annealed at a first elevated temperature for a first period of time. The perovskite precursor may be, for example, PbI₂. Suitable solvents include DMF, DMSO, and combinations thereof. The first elevated temperature may be in a range of from about 50° C. to about 100° C., or from about 60° C. to about 80° C. In one non-limiting example, the first elevated temperature is about 70° C. The first period of time may be, for example, from about 30 seconds to about 10 minutes, or from about 1 minute to about 5 minutes. In one non-limiting example, the period of time is about 2 minutes. Once annealed, a mixture of perovskite halide precursors and the hydrophobic molecule may be spin coated on top of the previously deposited and annealed layer. The thus formed layer may be annealed at a second elevated temperature for a second period of time to form a perovskite phase and remove extract organic chemicals. The second elevated temperature may be in a range of from about 50° C. to about 200° C., or from about 100° C. to about 175° C. In one non-limiting example, the second elevated temperature is about 150° C. The second period of time may be from about 1 minute to about 30 minutes, or from about 10 minutes to about 20 minutes. In one non-limiting example, the second period of time is about 15 minutes. The perovskite halide precursors may include any one or more of FAI, MACl, or MaBr. Other perovskite halide precursors are possible and nonetheless encompassed within the scope of the present disclosure. The annealing may be done in high humidity (˜70%) to obtain a desirable α-phase. However, this is not strictly necessary.

In a second non-limiting example method, the hydrophobic molecule may be incorporated into a perovskite through a solid diffusion method. For example, a solution of the hydrophobic molecule may be spun on glass to form a hydrophobic film. The hydrophobic film may then be placed on top of a pre-formed perovskite film (synthesized by any suitable method) to facilitate solid diffusion of the hydrophobic molecule into the perovskite film. The stacked films may then be post-annealed for a period of time to help the diffusion of the hydrophobic molecule before removing the hydrophobic film from the perovskite film. The period of time may range from about 30 seconds to about 10 minutes, or from about 3 minutes to about 7 minutes. In one non-limiting example, the period of time is about 5 minutes. Once the films are removed from each other, the residual hydrophobic molecule can be washed away from the perovskite surface by rinsing with a suitable solvent such as chlorobenzene.

Though both of the above-described methods are able to produce films with the hydrophobic molecule incorporated therein, solid diffusion is better adapted for large-scale manufacturing because it easier and quicker than the spin coating method. However, both methods produce similar performance characteristics, and other methods are entirely possible and nonetheless encompassed within the scope of the present disclosure. For example, the coordinated complex could be made through a liquid coating process. However, when the hydrophobic molecule is present in a solvent to be coated onto a perovskite, care should be taken to avoid damaging the perovskite with the solvent. The avoidance of a solvent is another reason that a solid diffusion method is better adapted for manufacturing than a liquid coating process.

In general, metal halide perovskites are very suitable for making optoelectronic devices because they can be processed in solution and do not need to be heated to high temperatures. Consequently, large-area films of metal halide perovskites can be deposited onto a wide range of substrate materials. Further, metal halide perovskites have a bandgap that can be tuned in the visible to infrared regions.

The compositions and methods described herein are useful for any process or device that involves a metal halide perovskite. Though solar cells are described for exemplary purposes herein, it is understood that the compositions and methods described herein may be implemented with a perovskite in any type of device or process. Non-limiting examples of such devices include photodetectors, light-emitting diodes (LEDs), and solar cells. A light-emitting diode (LED) is a semiconductor light source that emits light when current flows through it. Electrons in the semiconductor recombine with holes upon the application of a voltage and release energy in the form of photons. The color of the light, which corresponds to the energy of the photons, is determined by the energy required for the electrons to cross the band gap of the semiconductor. Metal halide perovskites emit light strongly, and are inexpensive, making them suitable for inexpensive LEDs. Furthermore, the methods and compositions described herein may be implemented with a perovskite used as a catalyst in a chemical synthesis.

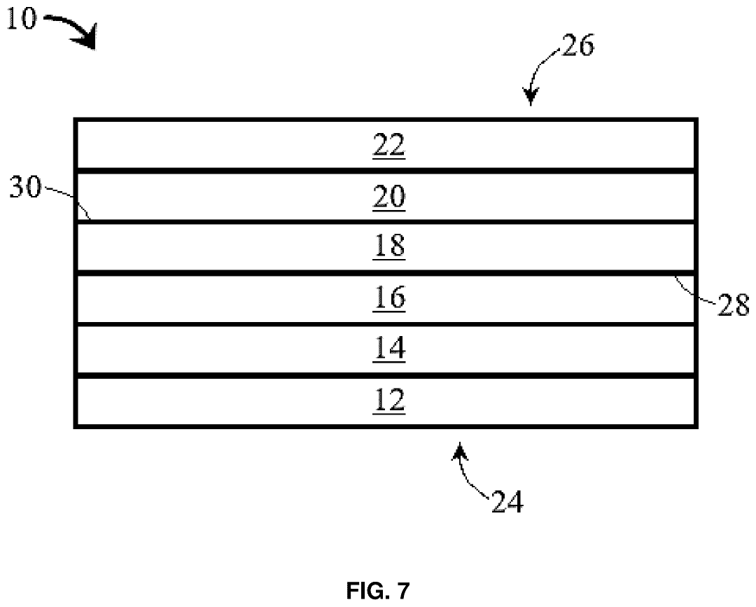

Referring now to FIG. 7, a non-limiting example of a perovskite solar cell 10 composed of a plurality of thin film layers in accordance with the present disclosure is depicted. The perovskite solar cell 10 may include a support 12, a front contact layer 14, a first semiconductor layer 16, a second semiconductor layer 18, a hole transport layer 20, and a back contact layer 22. The perovskite solar cell 10 has a sunny side 24 and an opposing side 26.

The support 12 may be any suitable transparent material such as glass or plastic. The support 12 provides structural support to the growing layer stack during manufacturing. The front contact layer 14 may generally be a transparent conductive material, such as a transparent conductive oxide. Non-limiting examples of transparent conductive oxides include SnO₂, indium tin oxide (ITO), In₂O₃, fluorine-doped tin oxide (FTO), and ZnO.

The first semiconductor layer 16 may be a transparent semiconductor material doped n-type, and may also be referred to as a window layer or an emitter layer. The first semiconductor layer 16 may be formed from any suitable semiconductor material such as, but not limited to, CdS, ZnS, CdSe, ZnO, or ZnSe.

The second semiconductor layer 18 may include a metal halide perovskite semiconductor material and may also be referred to as an absorber layer. The second semiconductor layer 18 may be formed from a metal halide perovskite having the formula ABX₃, where A is methylamine (MA), formamidine (FA), or cesium (Cs), B is lead (Pb), tin (Sn), or a combination thereof, and X is a halogen such as iodine (I), bromine (Br), or chlorine (Cl). The second semiconductor layer 18 may further include a hydrophobic molecule incorporated therein as described. In some embodiments, the hydrophobic molecule is a diphosphine molecule. In one non-limiting example, the hydrophobic molecule is dppp. The second semiconductor layer 18 may be made very thin, such as about 500 nm, and may be deposited at a low temperature, such as about 150° C.

The metal halide perovskite may be doped p-type such that a photovoltaic heterojunction 28 is formed between the first semiconductor layer 16 and the second semiconductor layer 18. It is understood, however, that this is merely one non-limiting example configuration, and many others are possible and encompassed within the scope of the present disclosure. For example, in other embodiments, the second semiconductor layer 18 may be doped n-type, and the first semiconductor layer 16 may be doped p-type.

Referring still to FIG. 7, light enters the perovskite solar cell 10 through the sunny side 24 and reaches the second semiconductor layer 18 where the light is absorbed within the material causing electrons to be excited to a higher energy state, and leaving behind empty states (“holes”). These excited electrons and holes may be referred to as charge carriers and are able to conduct and move freely within the material. The charge carriers may be collected by the conductive contacts 14, 22 to yield electrical power.

Any of the above-described layers of the perovskite solar cell 10 may be deposited or fabricated through know methods such as chemical bath deposition, chemical vapor deposition, thermal evaporation, sputtering, magnetron sputtering, physical vapor deposition, vapor transport deposition, molecular beam epitaxy, or electron beam evaporation. Any of the above-described layers may also include various dopants. The perovskite solar cell 10 may additionally include a variety of optional layers such as buffer layers.

As demonstrated in the examples herein, the perovskite solar cell 10 may exhibit improved stability to water and moisture because of the presence of the hydrophobic molecule in the second semiconductor layer 18.

### EXAMPLES

Perovskite solar cells were fabricated incorporating a small amount of dppp, and demonstrated significantly improved stability against water.

### Production of Dppp-Incorporated Perovskite Films by Spin Coating

50 μL of 1.3 M PbI₂ and 1.3 mM dppp in DMF and DMSO (volume ratio of 95:5) mixed solution was spin coated on a transparent conducting oxide substrate, and annealed at 70° C. for 2 minutes. Then, 200 μL of mixed FAI (60 mg/mL), MACl (6 mg/mL), MABr (6 mg/mL), and dppp (1 mg/mL) isopropanol solution was spin coated on top of the previously deposited PbI₂/dppp layer. The film was then annealed in air at 150° C. on a hot plate for 15 minutes to form a perovskite phase and remove extra organic chemicals. The annealing was done in high humidity (˜70%) to produce the desirable α-phase.

### Production of Dppp-Incorporated Perovskite Films by Solid Diffusion

Perovskite films were synthesized on a substrate by a two-step process. Then, a solution of dppp in chlorobenzene was spun on glass. A dppp film was then placed on top of the perovskite film to facilitate solid diffusion. The stacked films were then post-annealed for 5 minutes to help the diffusion of dppp before tearing away the top dppp film. The residual dppp was washed away from the perovskite surface by chlorobenzene rinsing.

### Solar Cells

Solar cells using the dppp-incorporated perovskites formed by the spin coating method and solar cells using the dppp-incorporated perovskites formed by the solid diffusion method showed similar performance.

The PCE of devices with and without dppp coordination were measured on devices having a configuration of ITO/SnO₂/FAPbI₃/Spiro-OMETAD/Au. The spiro-OMETAD is a hole transport layer. The current density-voltage (J-V) curve of the cells with and without dpp is shown in FIG. 4. The device without dppp showed a Voc of 1.11 V, a Jsc of 24.21 mA cm², a fill factor of 80.1%, and an efficiency of 21.52. The device with dppp showed a similar performance, with a Voc of 1.125 V, a Jsc of 24.19 mA cm², a fill factor of 78.7%, and an efficiency of 21.42%. The increased Voc indicates better film quality and fewer carrier recombinations by the passivated grain boundaries and defects. Thus, the dppp does not adversely impact device performance.

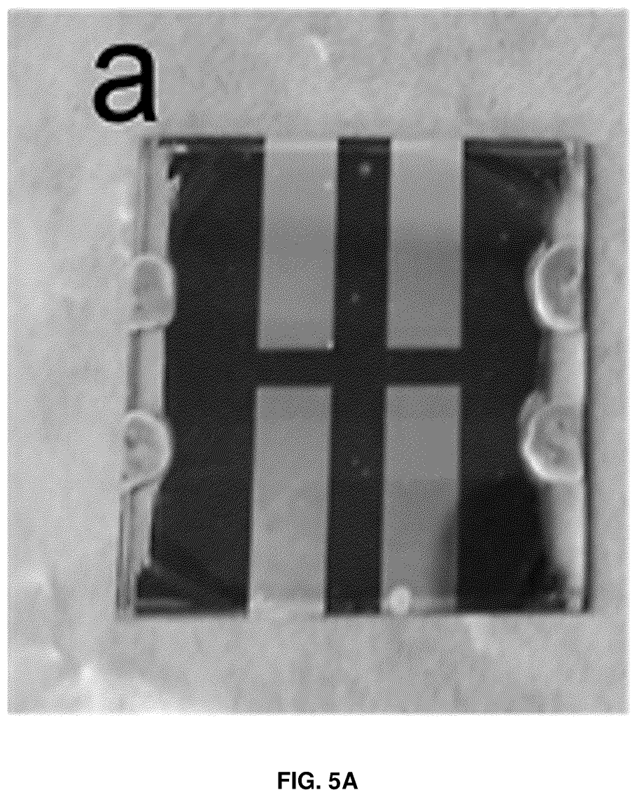

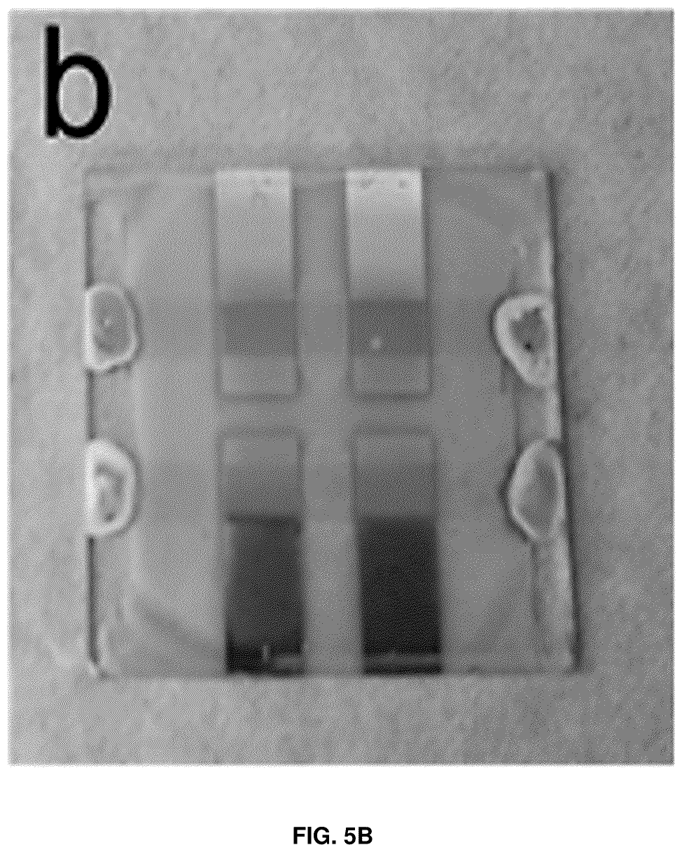

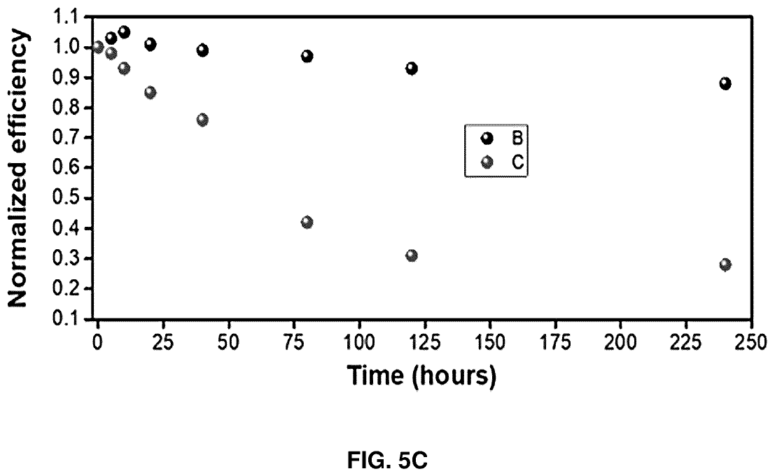

To test the stability of the devices, two devices with and without dppp were placed in ambient with an average humidity of 70% for more than 3 months. FIG. 5A shows a photograph of the device with dppp after storage. Surprisingly, the device with dppp coordination shows no color change after 3 months; the dark brown color seen in FIG. 5A means that the perovskite is still keeping the α-FAPbI₃ phase. In comparison, the device without dppp, shown in FIG. 5B, faded to a yellow color within 3 days, which was mainly due to moisture attack.

FIG. 5C is a chart of device efficiency change versus time. The cell with dppp (labeled “B”, shown with black dots in FIG. 5C) maintained 97% of its original efficiency at 80 hours, while the control device (labeled “C”, shown with red dots in FIG. 5C) decayed significantly after only 5 hours. The dppp device starts to decrease after 80, which may be due to a reaction with the metal contacts used for the example.

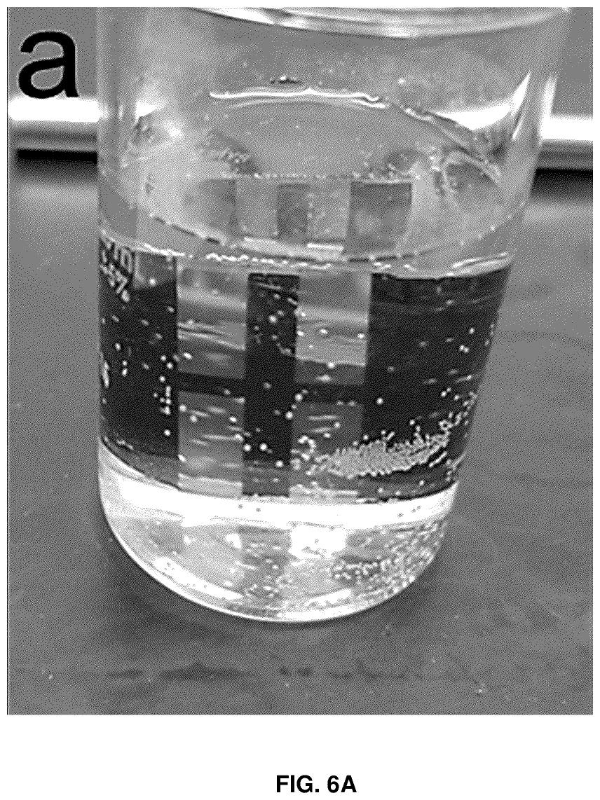

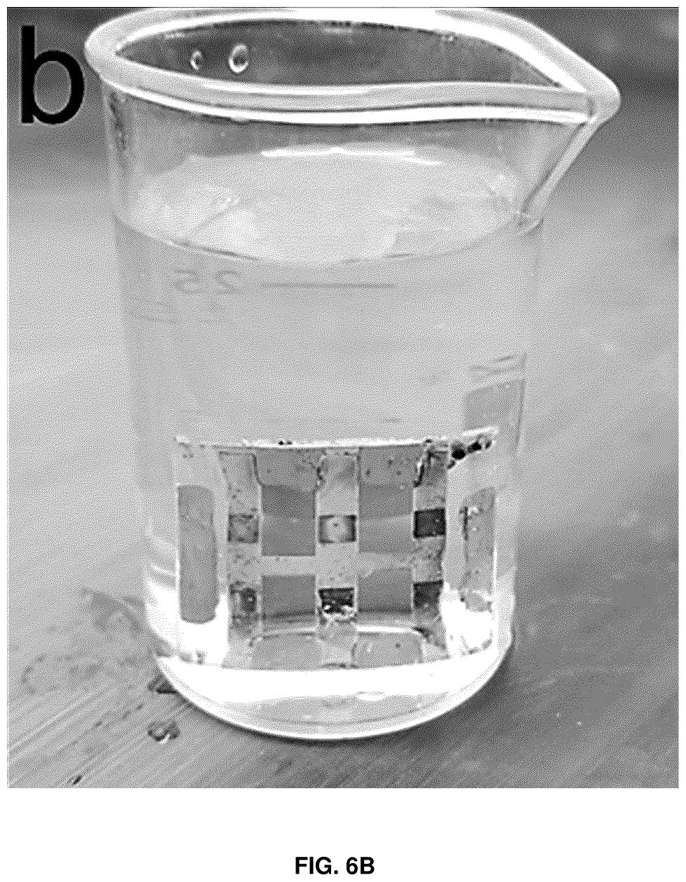

To further test the stability of perovskite with and without dppp, and eliminate the influence of Spiro-OMETAD, devices were fabricated in the configuration of ITO/PEDOT:PSS/FAPbI₃/C₆₀/bathocuproine (BCP)/silver. FIG. 6A is a photograph of the device with dppp coordination in a beaker of water for more than 10 hours. In comparison, the device without dppp, shown in FIG. 6B, turned to a yellowish color within 10 seconds. The water resistance for the device with dppp is due to: (1) the coordination between perovskite and dppp is strong (strong coordination bond), which will not be easily broken by water molecules (polarity or pressure); and (2) the hydrophobic effect is strong enough to prevent water from penetrating into the perovskite.

### Other Fabrication Methods

Dppp can also be incorporated into perovskite films by adding a desirable amount of dppp solution in perovskite solutions. Similar effects have been observed through this method.

Certain embodiments of the devices, compositions, and methods disclosed herein are defined in the above examples. It should be understood that these examples, while indicating particular embodiments of the invention, are given by way of illustration only. From the above discussion and these examples, one skilled in the art can ascertain the essential characteristics of this disclosure, and without departing from the spirit and scope thereof, can make various changes and modifications to adapt the devices, compositions, and methods described herein to various usages and conditions. Various changes may be made and equivalents may be substituted for elements thereof without departing from the essential scope of the disclosure. In addition, many modifications may be made to adapt a particular situation or material to the teachings of the disclosure without departing from the essential scope thereof.

What is claimed is:

1. A solar cell comprising:
a front contact comprising a first electrically conductive material;
a photovoltaic heterojunction on the front contact, wherein the photovoltaic heterojunction is formed between a first semiconductor layer and a second semiconductor layer, the second semiconductor layer comprising an absorber, wherein the absorber comprises a metal halide perovskite having a formula of ABX₃ wherein:
A is methylamine (MA), formamidine (FA), or cesium (Cs),
B is lead (Pb), tin (Sn), or a combination thereof; and
X is a halogen;
a hydrophobic molecule bonded to the metal halide perovskite, wherein the hydrophobic molecule coordinates with the lead or tin in the metal halide perovskite; and
a back contact comprising a second electrically conductive material on the absorber layer.

2. The solar cell of claim 1, wherein the hydrophobic molecule comprises a diphosphine.

3. The solar cell of claim 1, wherein the hydrophobic molecule comprises 1,3-bis(diphenylphosphino)propane (dppp).

4. The solar cell of claim 1, further comprising a hole transport layer disposed between the absorber layer and the back contact.

5. The solar cell of claim 4, wherein the hole transport layer comprises 2,2′,7,7′-tetrakis[N,N-di(4-methoxyphenyl)amino]-9,9′-spirobifluorene (spiro-OMETAD).

6. The solar cell of claim 1, wherein the perovskite comprises FAPbI₃.

7. The solar cell of claim 1, wherein the hydrophobic molecule is selected from the group consisting of: 1,3-bis(diphenylphosphino)propane (dppp), 1,1-bis(diphenylphosphino)methane (dppm), bis(dicyclohexylphosphinoe)methane (dcpm), 1,2-bis(dimethylphosphino)ethane (dmpe), bis(diisopropylphosphino)methane (dippm), 1,2-bis(diisopropylphosphino(ethane) (dippe), 1,3-bis(diisopropylphosphino)propane (dippp), 1,2-bis(diphenylphosphino)ethane (dppe), bis(dimethylphosphino)methane (dmpm), 1,3-bis(dicyclohexylphosphino)propane (dcpp), ethane-1,2-diylbis[(2-methoxyphenyl)phenylphosphane] (DIPAMP), bis(dicyclohexylphosphino)ethane (dcpe), 1,3-bis(dimethylphosphino)propane (dmpp), 1,4-bis(diphenylphosphino)butane (dppb), diphosphine-1,1,2,2-tetraphenyl propane, 1,1-bis(diphenylphosphino)ethylene, O-isopropylidene-2,3-dihydroxy-1,4-bis(diphenylphosphino)butane (DIOP), butane-2,3-diylbis(diphenylphosphane) (BINAP), butane-2,3-diylbis(diphenylphosphane) (chiraphos), 4,5-bis(diphenylphosphino)-9,9-dimethylxanthene (xantphos), 4,4,4′,4′,6,6′-hexamethyl-2,2′-spirobichromane-8,8′-diylbis(diphenylphosphane) (SPANphos), 4,4′-bi-1,3-benzodioxole-5,5′-diylbis(diphenylphosphane) (SEGPHOS), 1,1′-bis(diphenylphosphino)ferrocene (dppf), 1,2-phenylenebis(2,5-dimethylphospholane) (Me-DuPhos), and combinations thereof.

8. The solar cell of claim 1, wherein the hydrophobic molecule comprises a dinitrogen compound.

9. The solar cell of claim 1, wherein the hydrophobic molecule is selected from the group consisting of: 4,4′-bipyridine, 4,4′-ethylenedipyridine, 4,4′-trimethylenedipyridine, (1R,2R)-(−)-1,2-diaminocyclohexane, 2,2′-bipyridine, 2,2′-dipyridylamine, 1,10-phenanthroline, benzil bis(thiosemicarbazone), and combinations thereof.

10. The solar cell of claim 1, wherein the hydrophobic molecule comprises a metal-dioxygen complex.

11. A solar cell comprising:
a front contact comprising a first electrically conductive material;
an absorber on the front contact, wherein the absorber comprises a metal halide perovskite having a formula of ABX₃ wherein:
A is methylamine (MA), formamidine (FA), or cesium (Cs),
B is lead (Pb), tin (Sn), or a combination thereof; and
X is a halogen;
a hydrophobic molecule bonded to the metal halide perovskite, wherein the hydrophobic molecule coordinates with the lead or tin in the metal halide perovskite;
a back contact comprising a second electrically conductive material on the absorber layer; and
a hole transport layer disposed between the absorber layer and the back contact.

12. The solar cell of claim 11, wherein the hole transport layer comprises 2,2′,7,7′-tetrakis[N,N-di(4-methoxyphenyl)amino]-9,9′-spirobifluorene (spiro-OMETAD).

13. The solar cell of claim 11, wherein the perovskite comprises FAPbI₃.

14. The solar cell of claim 11, the hydrophobic molecule comprises 1,3-bis(diphenylphosphino)propane (dppp).

15. The solar cell of claim 11, wherein:
the perovskite comprises FAPbI₃; and
the hydrophobic molecule comprises 1,3-bis(diphenylphosphino)propane (dppp).
